(19) United States
(12) Patent Application Publication
(10) Pub. No.: US 2020/0070196 A1
(43) Pub. Date: Mar. 5, 2020

(54) SUBSTRATE PROCESSING APPARATUS, SUBSTRATE PROCESSING METHOD, AND STORAGE MEDIUM

(71) Applicant: TOKYO ELECTRON LIMITED, Tokyo (JP)

(72) Inventors: Fumihiro KAMIMURA, Kosi City (JP); Hiroshi KOMIYA, Koshi City (JP); Nobuhiro OGATA, Koshi City (JP); Takahisa OTSUKA, Koshi City (JP)

(21) Appl. No.: 16/553,984

(22) Filed: Aug. 28, 2019

(30) Foreign Application Priority Data
Aug. 30, 2018 (JP) 2018-161845

(51) Int. Cl. B05B 15/58; B05D 1/02; H01L 21/67; B05B 12/08

(52) U.S. Cl. CPC B05B 15/58; B05B 12/081; H01L 21/67017; B05D 1/02

(57) ABSTRACT

There is provided a substrate processing apparatus including: a nozzle configured to eject a processing liquid onto a substrate; a standby section having an opening, wherein the nozzle is inserted into the opening to stand by in the standby section; a supply path through which the processing liquid is supplied to the nozzle; a discharge path through which the processing liquid is discharged from the standby section; a circulation path formed by connecting the nozzle, the standby section, the supply path, and the discharge path; and an atmospheric-blocking mechanism provided in the circulation path to block an inside of the circulation path and a surrounding of the substrate from each other.

### CROSS-REFERENCE TO RELATED APPLICATION

This application is based upon and claims the benefit of priority from Japanese Patent Application No. 2018-161845, filed on Aug. 30, 2018, the entire contents of which are incorporated herein by reference.

### TECHNICAL FIELD

Embodiments of the present disclosure relate to a substrate processing apparatus, a substrate processing method, and a non-transitory computer-readable storage medium.

### BACKGROUND

Conventionally, in a substrate processing apparatus that performs a liquid process on a substrate such as a semiconductor wafer (hereinafter, also referred to as a “wafer”), there is known a technique for allowing a nozzle configured to eject a processing liquid to wait in a standby section when no liquid process is performed on the substrate, thus dummy-dispensing a processing liquid. Such a dummy dispensing is performed to stably supply the processing liquid onto the substrate (see Patent Document 1).

### PRIOR ART DOCUMENT

### Patent Documents

Patent Document 1: Japanese Laid-Open Patent Publication No. H10-074725

### SUMMARY

According to an embodiment of the present disclosure, there is provided a substrate processing apparatus including: a nozzle configured to eject a processing liquid onto a substrate; a standby section having an opening, wherein the nozzle is inserted into the opening to stand by in the standby section; a supply path through which the processing liquid is supplied to the nozzle; a discharge path through which the processing liquid is discharged from the standby section; a circulation path formed by connecting the nozzle, the standby section, the supply path, and the discharge path; and an atmospheric-blocking mechanism provided in the circulation path to block an inside of the circulation path and a surrounding of the substrate from each other.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view illustrating a schematic configuration of a substrate processing system according to an embodiment.

FIG. 2 is a schematic view illustrating a specific exemplary configuration of a processing unit.

FIG. 3 is a view illustrating configurations of a processing liquid supply part, a supply path and a discharge path according to an embodiment.

FIG. 4 is a view for explaining a flow of a processing liquid according to the embodiment.

FIG. 5 is a view for explaining a flow of a processing liquid according to the embodiment.

FIG. 6 is a view illustrating a configuration of an atmosphere blocking mechanism according to a first modification of the embodiment.

FIG. 7 is a cross-sectional view taken along line A-A in FIG. 6.

FIG. 8 is a view for explaining an operation of the atmosphere blocking mechanism according the first modification of the embodiment.

FIG. 9 is a view for explaining an operation of the atmosphere blocking mechanism according the first modification of the embodiment.

FIG. 10 is a view illustrating a configuration of an atmosphere blocking mechanism according to a second modification of the embodiment.

FIG. 11 is a view illustrating a configuration of an atmosphere blocking mechanism according to a third modification of the embodiment.

FIG. 12 is a view illustrating a configuration of an atmosphere blocking mechanism according to a fourth modification of the embodiment.

FIG. 13 is a view illustrating a configuration of an atmosphere blocking mechanism according to a fifth modification of the embodiment.

FIG. 14 is a view illustrating a configuration of the atmosphere blocking mechanism according to the fifth modification of the embodiment.

FIG. 15 is a view illustrating a configuration of an atmosphere blocking mechanism according to a sixth modification of the embodiment.

FIG. 16 is a view illustrating a configuration of the atmosphere blocking mechanism according to the sixth modification of the embodiment.

FIG. 17 is a view showing a specific configuration of the discharge path according to the embodiment.

FIG. 18 is a timing chart illustrating a specific example of a behavior pattern of a control valve according to the embodiment.

FIG. 19 is a view illustrating a specific configuration of a discharge path according to a seventh modification of the embodiment.

FIG. 20 is a timing chart illustrating a specific example of a behavior pattern of a control valve according to the seventh modification of the embodiment.

FIG. 21 is a view illustrating a specific configuration of a discharge path according to an eighth modification of the embodiment.

FIG. 22 is a view illustrating a specific configuration of a discharge path according to a ninth modification of the embodiment.

### DETAILED DESCRIPTION

Hereinafter, a substrate processing apparatus, a substrate processing method, and a storage medium according to embodiments of the present disclosure will be described in detail with reference to the accompanying drawings. Further, the present disclosure is not limited to embodiments described below, in addition, it should be noted that the drawings are schematic, and the relationships between dimensions of respective elements, the ratios of the respective elements, and the like may differ from reality. Also, there may be a case where the relationship of dimensions and the ratios differ from each other between the drawings.

Conventionally, in a substrate processing apparatus that performs a liquid process on a substrate such as a semiconductor wafer (hereinafter, also referred to as a “wafer”), there is known a technique for allowing a nozzle configured to eject a processing liquid to wait in a standby section when no liquid process is performed on the substrate, thus performing a dummy dispensing on the processing liquid. Such a dummy dispensing is performed to stably supply the processing liquid onto the substrate.

In addition, in the state in which the nozzle is on standby in the standby section, a supply path through which the processing, liquid is supplied to the nozzle and a discharge path through which the processing liquid is discharged from the standby section are connected to each other to form a circulation path. This makes it possible to circulate the dummy-dispensed processing liquid inside the substrate processing apparatus.

Meanwhile, in a case of performing a liquid process with different types of processing liquids, when a processing liquid flowing through the circulation path and a processing liquid for processing the substrate are different from each other, the different types of processing liquids may react with each other through an atmosphere to generate impurities or the like. Such impurities may contaminate the substrate and the processing liquids.

In this regard, a demand existed for a technique for stably supplying processing liquids during substrate processing by suppressing an internal atmosphere of the circulation path and an atmosphere around the substrate from being mixed with each other while reducing an amount of the processing liquids to be discarded by the dummy dispensing or the like.

### <Outline of Substrate Processing System>

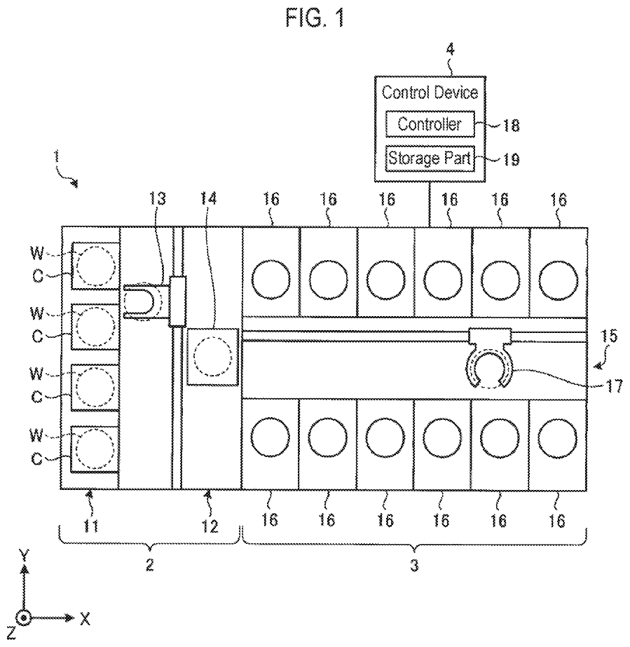

First, a schematic configuration of a substrate processing system 1 according to an embodiment will be described with reference to FIG. 1. FIG. 1 is a view illustrating the schematic configuration of the substrate processing system 1 according to the embodiment. In addition, the substrate processing system 1 is an example of a substrate processing apparatus. For the clarification of a positional relationship, an X-axis direction, a Y-axis direction and a Z-axis direction, which are orthogonal to one another, are defined in the following description and a positive Z-axis direction is defined as a vertical upward direction.

As illustrated in FIG. 1, the substrate processing system 1 includes a loading/unloading station 2, and a processing station 3. The loading/unloading station 2 and the processing station 3 are provided adjacent to each other.

The loading/unloading station 2 includes a carrier mounting part 11 and a transfer part 12. A plurality of carriers C is mounted on the carrier mounting part 11. Each of the carrier C accommodates a plurality of substrates, namely semiconductor wafers W (hereinafter, referred to as “wafers W”) in this embodiment, in a horizontal posture.

The transfer part 12 is provided adjacent to the carrier mounting part 11, and includes a substrate transfer device 13 and a delivery part 14. The substrate transfer device 13 includes a wafer holding mechanism configured to hold the wafer W. In addition, the substrate transfer device 13 is configured to move in horizontal and vertical directions and swing about a vertical axis thereof. The substrate transfer device 13 transfers the wafer W between the carrier C and the delivery part 14 using the wafer holding mechanism.

The processing station 3 is provided adjacent to the transfer part 12. The processing station 3 includes a transfer part 15 and a plurality of processing units 16. The plurality of processing units 16 are arranged at the opposite sides of the transfer part 15.

The transfer part 15 includes a substrate transfer device 17 provided therein. The substrate transfer device 17 includes a wafer holding mechanism configured to hold the wafer W. In addition, the substrate transfer device 17 is configured to move in the horizontal and vertical directions and swing about a vertical axis thereof. The substrate transfer device 17 transfers the wafer W between the delivery part 14 and the processing unit 16 using the wafer holding mechanism.

Each of the processing units 16 performs a predetermined process on the wafer W transferred by the substrate transfer device 17.

Further, the substrate processing system 1 includes a control device 4. The control device 4 is, for example, a computer, and includes a controller 18 and a storage part 19. A program for controlling various processes executed in the substrate processing system 1 is stored in the storage part 19. The controller 18 controls the operation of the substrate processing system 1 by reading and executing the program stored in the storage part 19.

The program may be recorded in a non-transitory computer-readable storage medium, and may be installed on the storage part 19 of the control device 4 from the storage medium. Example of the computer-readable storage medium may include a hard disk (HD), a flexible disk (FD), a compact disk (CD), a magneto-optical disk (MO), a memory card and the like.

In the substrate processing system 1 configured as above, first, the substrate transfer device 13 of the loading/unloading station 2 takes out the wafer W from the carrier C mounted on the carrier mounting part 11 and mounts the same on the delivery part 14. The wafer W mounted on the delivery part 14 is picked up by the substrate transfer device 17 in the processing station 3, and is loaded into the processing unit 16.

The wafer W loaded into the processing unit 16 is processed by the processing unit 16, and subsequently is unloaded from the respective processing unit 16. The processed wafer W is mounted on the delivery part 14 by the substrate transfer device 17. The processed wafer W mounted on the delivery part 14 is returned to the respective carrier C in the carrier mounting part 11 by the substrate transfer device 13.

### <Configuration of Processing Unit>

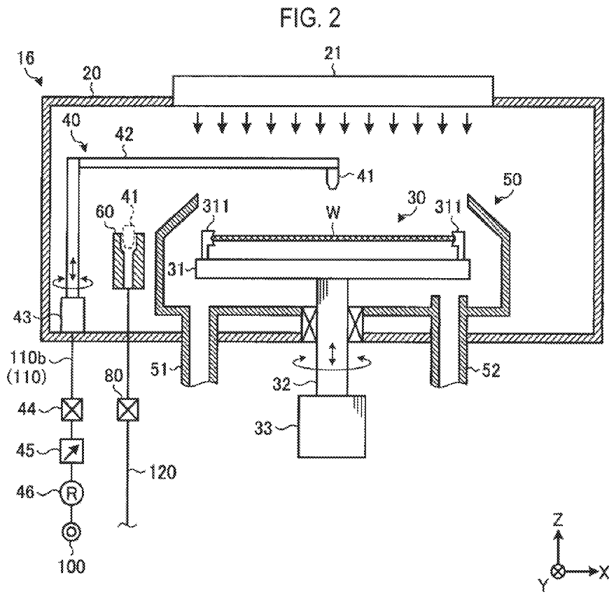

Next, a configuration of the processing unit 16 will be described with reference to FIG. 2. FIG. 2 is a schematic view illustrating a specific exemplary configuration of the processing unit 16. As illustrated in FIG. 2, the processing unit 16 includes a chamber 20, a substrate processing part 30, a processing liquid ejection part 40, a recovery cup 50, and a standby section 60.

The chamber 20 accommodates the substrate processing part 30, the processing liquid ejection part 40, the recovery cup 50, and the standby section 60. A fan filter unit (FFU) 21 is provided in a ceiling portion of the chamber 20. The FFU 21 is provided to form a down-flow within the chamber 20.

The substrate processing part 30 includes a holder 31, a supporting column 32, and a driver 33, and performs a liquid process on the wafer W held by the holder 31. The holder 31 holds the wafer W in a horizontal posture. The supporting column 32 is a member extending in the vertical direction. The supporting column 32 is rotatably supported by the driver 33 at the base end thereof, and horizontally supports the holder 31 on the tip end thereof. The driver 33 rotates the supporting column 32 about a vertical axis.

The substrate processing part 30 rotates the supporting column 32 using the driver 33 to rotate the holder 31 supported by the supporting column 32. Thus, the wafer W held by the holder 31 is rotated.

A holding member 311 configured to hold the wafer W from the sides thereof is provided on an upper surface of the holder 31 of the substrate processing part 30. The wafer W is horizontally held by the holding member 311 in the state of being slightly separated from the upper surface of the holder 31. The wafer W is held by the holder 31 in the state in which a front surface on which substrate processing is to be performed is oriented upward.

The processing liquid ejection part 40 ejects the processing liquid onto the wafer W. The processing liquid ejection part 40 includes a nozzle 41, an arm 42 configured to horizontally support the nozzle 41, and a pivoting/lifting mechanism 43 configured to pivot and lift the arm 42. Although in FIG. 2 there is shown an example in which one nozzle 41 is provided, a plurality of nozzles 41 may be provided in the arm 42.

The nozzle 41 is coupled to the processing liquid supply part 100 via a branch line 110b of the supply path 110. A valve 44, a flow rate adjuster 45, and a regulator 46 are provided in the branch line 110b. A predetermined processing liquid supplied from the processing liquid supply part 100 is ejected from the nozzle 41. Details of the processing liquid supply part 100 and the supply path 110 will be described later.

The recovery cup 50 is disposed so as to surround the holder 31, and collects the processing liquid scattering from the wafer W with the rotation of the rotation of the holder 31. A drainage port 51 is formed in a bottom portion of the recovery cup 50. The processing liquid collected by the recovery cup 50 is drained from the drainage port 51 outward of the processing unit 16, in addition, an exhaust port 52 is formed in the bottom portion of the recovery cup 50 to discharge the gas supplied from the FFU 21 outward of the processing unit 16.

When the nozzle 41 does not eject the processing liquid onto the wafer W, the nozzle 41 is on standby in the standby section 60. The nozzle 41 is subjected to the dummy dispensing process when the nozzle 41 is on standby in the standby section 60.

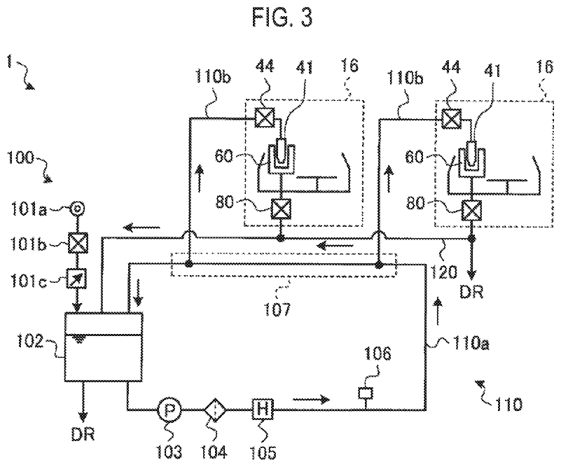

The dummy dispensing process may be a process for appropriately ejecting the processing liquid from the nozzle 41 that is on standby and is not ejecting the processing liquid onto the wafer W, in order to prevent the deterioration of the processing liquid. The processing liquid ejected from the nozzle 41 is discharged to a tank 102 (see FIG. 3) through a discharge path 120.

A blocking valve 80 is provided in the discharge path 120. The blocking valve 80 is an example of the atmosphere blocking mechanism.

<Configuration of Processing Liquid Supply Part>

Next, configurations of the processing liquid supply part 100, the supply path 110, and the discharge path 120 for the processing liquid, which are included in the substrate processing system 1, will be described with reference to FIG. 3. FIG. 3 is a view illustrating the configurations of the processing liquid supply part 100, the supply path 110, and the discharge path 120 according to the embodiment. Components such as the processing liquid supply part 100, the supply path 110, and the discharge path 120 described below can be controlled by the controller 18.

As illustrated in FIG. 3, the processing liquid supply part 100 according to the embodiment includes a processing liquid source 101a, a valve 101b, a flow rate adjuster 101c, the tank 102, and a circulation line 110a.

The processing liquid source 101a is coupled to the tank 102 via the valve 101b and the flow rate adjuster 101c. Thus, the processing liquid supply part 100 is capable of storing the processing liquid in the tank 102 by supplying the processing liquid from the processing liquid source 101a into the tank 102. The tank 102 is connected to a drainage part (DR) such that the processing liquid stored in the tank 102 may be discharged to the drainage port (DR).

The circulation line 110a is a circulation line that starts from the tank 102 and returns to the tank 102. A pump 103, a filter 104, a heater 105, and a thermocouple 106 are provided in the circulation line 110a in this order from the upstream side with reference to the tank 102.

The pump 103 forms a circulating flow of the processing liquid, which starts from the tank 102, passes through the circulation line 110a, and returns to the tank 102. The filter 104 removes contaminants such as particles contained in the processing liquid that circulates through the circulation line 110a.

The heater 105 heats the processing liquid circulating through the circulation line 110a. The thermocouple 106 measures a temperature of the processing liquid circulating through the circulation line 110a. Therefore, the controller 18 is capable of controlling the temperature of the processing liquid circulating through the circulation line 110a using the heater 105 and the thermocouple 106.

One or more branch lines 110b are connected to a connection area 107 defined in the circulation line 110a. Each of the branch lines 110b supplies the processing liquid flowing through the circulation line 110a into the respective processing unit 16. In addition to the valve 44, the flow rate adjuster 45, and the regulator 46 described above, a filter, a temperature sensor, and the like may be provided in the branch line 110b.

As described above, in the substrate processing system 1, the processing liquid stored in the tank 102 is supplied into the nozzle 41 through the supply path 110 composed of the circulation line 110a and the branch line 110b.

In addition, in the substrate processing system 1, the standby section 60 of each processing unit 16 is coupled to the tank 102 through the discharge path 120. The discharge path 120 is connected to a drainage part (DR) so that the processing liquid flowing through the discharge path 120 can be discharged to the drainage part (DR).

<Flow of Processing Liquid>

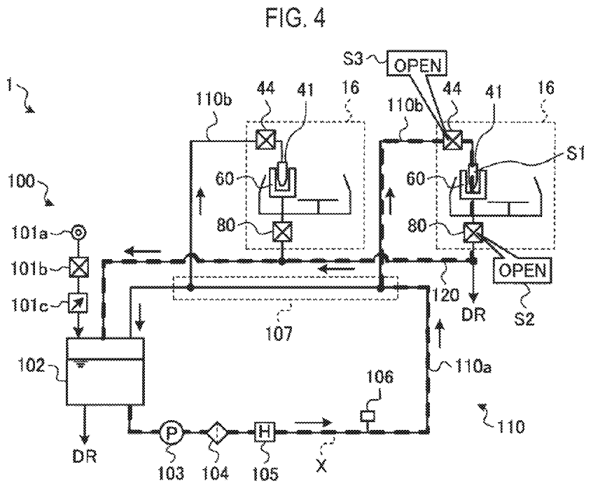

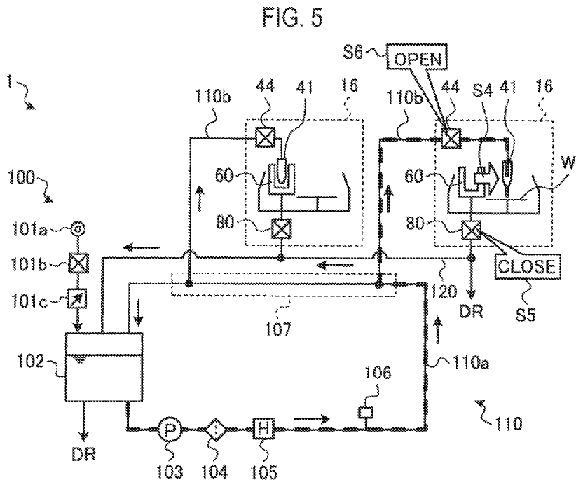

Next, the flow of the processing liquid in the substrate processing system 1 will be described with reference to FIGS. 4 and 5. FIGS. 4 and 5 are views for explaining the flow of the processing liquid according to the embodiment.

As illustrated in FIG. 4, first, the processing unit 16 causes the nozzle 41 to standby in the standby section 60 (in step S1). Subsequently, the processing unit 16 opens the blocking valve 80 provided in the discharge path 120 (in step S2).

Subsequently, the processing unit 16 opens the valve 44 provided in the branch line 110b of the supply path 110 (in step S3). Thus, in the embodiment, as indicated by a bold broken line in FIG. 4, it is possible to circulate the processing liquid through a circulation path X that is constituted with the supply path 110 composed of the circulation line 110a and the branch line 110b, the nozzle 41, the standby section 60, and the discharge path 120.

That is to say, in the embodiment, in the case where the nozzle 41 is subjected to the dummy-dispensing process in the standby section 60, all the dummy-dispensed processing liquid can be collected in the tank 102. Therefore, according to the embodiment, it is possible to reduce the consumption amount of the processing liquid.

Subsequently, as illustrated in FIG. 5, the processing unit 16 moves the nozzle 41 above the wafer W loaded thereinto (in step S4). At this time, the processing unit 16 closes the blocking valve 80 in the discharge path 120 (in step S5). This makes it possible to suppress an atmosphere in the discharge path 120 and an atmosphere around the water W from being mixed with each other.

That is to say, in the embodiment, when the nozzle 41 is released from the standby section 60, it is possible to suppress the mixing of an atmosphere in the circulation path X illustrated in FIG, 4 and the atmosphere around the wafer W by closing the blocking valve 80 used as an atmosphere blocking mechanism.

Subsequently, the processing unit 16 opens the valve 44 (in step S6). As a result, as indicated by a bold broken line in FIG. 5, the processing liquid is ejected onto the wafer W through the supply path 110 and the nozzle 41.

In the embodiment, as illustrated in FIG. 4, the processing liquid adjusted to have a predetermined temperature by the heater 105 and the thermocouple 106 may be continuously subjected to the dummy-dispensing process in the nozzle 41 while the nozzle 41 is on standby in the standby section 60. Thus, when the ejection of the processing liquid from the nozzle 41 onto the water W is started, it is possible to eject the processing liquid of which the temperature has not dropped from the predetermined temperature, onto the wafer W.

Therefore, according to the embodiment, it is possible to eject the processing liquid having the predetermined temperature onto the wafer W from the start of ejection, thus implementing a stable liquid process with less variation due to a change in temperature.

<Modifications of Atmosphere Blocking Mechanism>

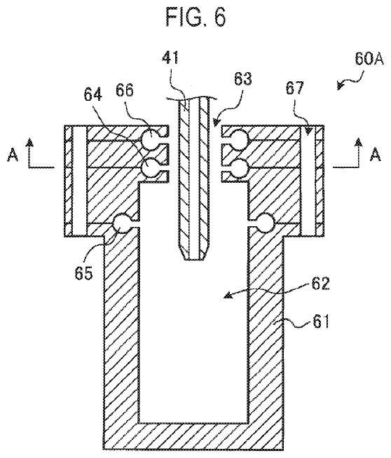

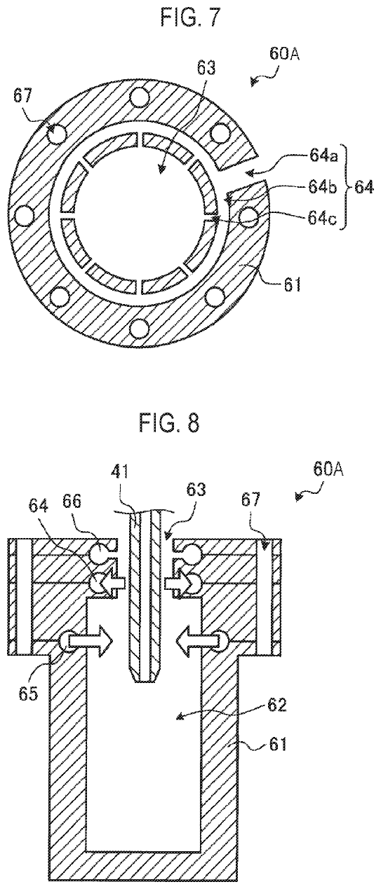

Next, various modifications of the atmosphere blocking mechanism for suppressing the mixing of the atmosphere in the circulation path X and the atmosphere around the wafer W will be described with reference to FIGS. 6 to 16. FIG. 6 is a view illustrating a configuration of an atmosphere blocking mechanism according to a first modification of the embodiment, and FIG. 7 is a cross-sectional view taken along the line A-A in FIG. 6.

As illustrated in FIG. 6, a standby section 60A according to the first modification includes a substantially cylindrical main body 61. The main body 61 includes a substantially cylindrical standby room 62 formed therein, and an opening 63 formed at one end (upper end in FIG. 6). A tip end of the nozzle 41 may be inserted into the opening 63 of the standby section 60A so that the nozzle 41 stands by in the standby room 62.

In the first modification, a gas suction portion 64 and gas ejection portions 65 and 66 are connected to the opening 63 or provided adjacent to the opening 63. In the example illustrated in FIG. 6, the gas suction portion 64 and the gas ejection portion 66 are connected to the opening 63, and the gas ejection portion 65 is provided adjacent to the opening 63.

As illustrated in FIG. 7, the gas suction portion 64 includes an outer connection line 64a, an annular line 64b, and a plurality of inner connection lines 64c. The outer connection line 64a is coupled to a gas suction mechanism (not illustrated) such as a pump via an outer pipe (not illustrated). The annular line 64b is formed in a substantially annular shape inside the main body 61.

The plurality of inner connection lines 64c interconnect the annular line 64b and the opening 63. The plurality of inner connection lines 64c are substantially evenly arranged in the circumferential direction of the annular line 64b.

By operating the gas suction mechanism (not illustrated), the gas suction portion 64 can suck an atmosphere gas in the opening 63 via the outer connection line 64a, the annular line 64b, and the plurality of inner connection lines 64c.

In addition, the gas ejection portions 65 and 66 may have the same configuration as the gas suction portion 64 illustrated in FIG. 7. The gas ejection portions 65 and 66 are coupled to a gas source (not illustrated) configured to supply an inert gas such as a nitrogen gas via an outer pipe (not illustrated).

By operating the gas source, the gas ejection portions 65 and 66 may eject the inert gas to the opening 63 or the vicinity of the opening 63 through the outer connection line, the annular line, and the plurality of inner connection lines.

In addition, the standby section 60A of the first modification may be formed by forming predetermined grooves or holes in a plurality of metal rings, and fixing the plurality of metal rings thus formed using fixing screw holes 67. With this manner, it is possible to easily manufacture the standby section 60A in which the outer connection line, the ring line, the plurality of inner connection lines and the like are formed.

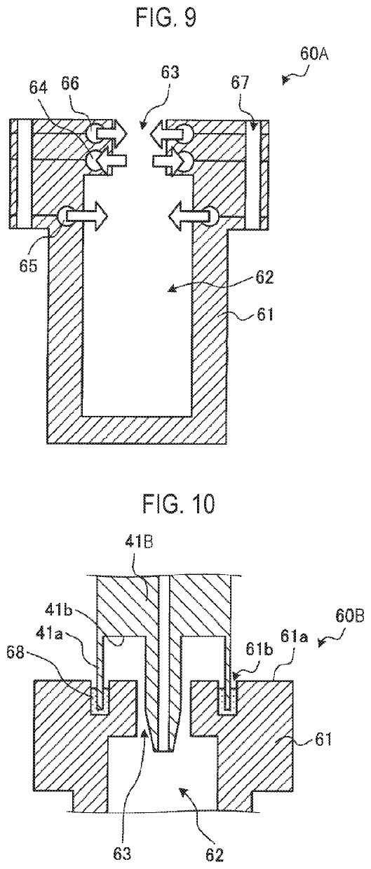

Next, a specific operation of the atmosphere blocking mechanism according to the first modification will be described with reference to FIGS. 8 and 9. FIGS. 8 and 9 are views for explaining the operation of the atmosphere blocking mechanism according to the first modification of the embodiment.

As illustrated in FIG. 8, the processing unit 16 according to the first modification sucks the atmosphere gas in the vicinity of the nozzle 41 from the gas suction portion 64 when the nozzle 41 is on standby in the standby section 60A, and ejects the inert gas from the gas ejection portion 65 to the vicinity of the nozzle 41. At this time, the suction and the ejection are performed so as to balance the suction amount of the atmosphere gas from the gas suction portion 64 and the ejection amount of the inert gas from the gas ejection portion 65.

With this configuration, it is possible to suppress the atmosphere outside the standby section 60A (e.g., around the wafer W) from flowing into the standby room 62 through the opening 63 when the nozzle 41 is on standby in the standby section 60A.

Further, as illustrated in FIG. 9, when the nozzle 41 is released from the standby section 60A, the processing unit 16 of the first modification sucks the atmosphere of the opening 63 from the gas suction portion 64 and ejects the inert gas from the gas ejection portions 65 and 66 to the opening 63 or the vicinity of the opening 63.

With this configuration, it is possible for the processing unit 16 of the first modification to suppress an atmosphere outside the standby section 60A (e.g., around the wafer W) from flowing into the standby room 62 through the opening 63 when the nozzle 41 is released from the standby section 60A.

That is to say, according to the first modification, either when the nozzle 41 is on standby in the standby section 60A or when the nozzle 41 is released from the standby section 60A, it is possible to suppress the atmosphere in the circulation path X and the atmosphere around the water W from being mixed with each other.

In some embodiments, as illustrated in FIG. 6 and the like, an inner diameter of the opening 63 formed in the standby section 60A may be about twice an outer diameter of the nozzle 41. Thus, even if the position of the nozzle 41 is slightly displaced, it is possible to insert the nozzle 41 into the opening 63 with no problem, and to effectively suppress the atmosphere around the wafer W from flowing into the standby room 62 through the opening 63.

The arrangement and configuration of the gas suction portion 64 and the gas ejection portions 65 and 66 illustrated in FIG. 6 and the like are merely exemplary embodiments. Any arrangement and configuration may be adopted as long as they are possible to suppress the atmosphere around the wafer W from flowing into the standby room 62 through the opening 63.

FIG. 10 is a view illustrating a configuration of an atmosphere blocking mechanism according to a second modification of the embodiment. As illustrated in FIG. 10, a nozzle 41B of the second modification includes a wall portion 41a formed so as to surround the ejection portion of the nozzle 41B. The wall portion 41a is provided in the vicinity of the ejection portion of the nozzle 41B, and is formed to protrude in the ejection direction of the nozzle 41B from a lower surface 41b substantially perpendicular to the ejection direction of the nozzle 41B.

In addition, a recess 61b is formed in an upper surface 61a of the standby section 60B at a position corresponding to the wall portion 41a of the nozzle 41B. That is to say, in the second modification, the wall portion 41a of the nozzle 41B and the recess 61b in the standby section 60B are formed to be fitted to each other. In addition, a water seal 68 such as deionized water (DIW) is supplied into the recess 61b of the standby section 60B from a water seal source (not illustrated).

As illustrated in FIG. 10, the processing unit 16 of the second modification is capable of sealing the outside of the standby section 60B (e.g., around the wafer W) and the standby room 62 from each other using the water seal 68 when the nozzle 41B is on standby in the standby section 60B. That is to say, in the second modification, the water seal 68 constitutes a seal mechanism.

Therefore, according to the second modification, it is possible to suppress the atmosphere in the circulation path X illustrated in FIG. 4 and the atmosphere around the water W from being mixed with each other when the nozzle 41B is on standby in the standby section 60B.

In the second modification, by using a water seal discharge mechanism (not illustrated), the water seal 68 stored in the recess 61b may be discharged with an increase in water level when the wall portion 41a enters the recess 61b. This makes it possible to suppress a liquid such as DIW from overflowing toward the opening 63 by the increase in water level of the water seal 68 due to the entry of the wall portion 41a into the recess 61B.

FIG. 11 is a view illustrating a configuration of an atmosphere blocking mechanism according to a third modification of the embodiment. As illustrated in FIG. 11, a nozzle 41C of the third modification includes an O-ring 69 provided on a lower surface 41b thereof. The O-ring 69 is provided at a position where the nozzle 41C is brought into contact with an upper surface 61a of a standby section 60C.

As illustrated in FIG. 11, the processing unit 16 of the third modification is capable of sealing the outside of the standby section 60C (e.g., around the wafer W) and the standby room 62 from each other by bringing the O-ring 69 into close contact with the upper surface 61a when the nozzle 41C is on standby in the standby section 60C. That is to say, in the third modification, the O-ring 69 constitutes a seal mechanism.

Therefore, according to the third modification, when the nozzle 41C is on standby in the standby section 60C, it is possible to suppress the atmosphere in the circulation path X illustrated in FIG. 4 and the atmosphere around the wafer W from being mixed with each other. In addition, although in FIG. 11 three is described an example of using the O ring 69 as a seal mechanism, V-like packing or the like may be used as a seal mechanism.

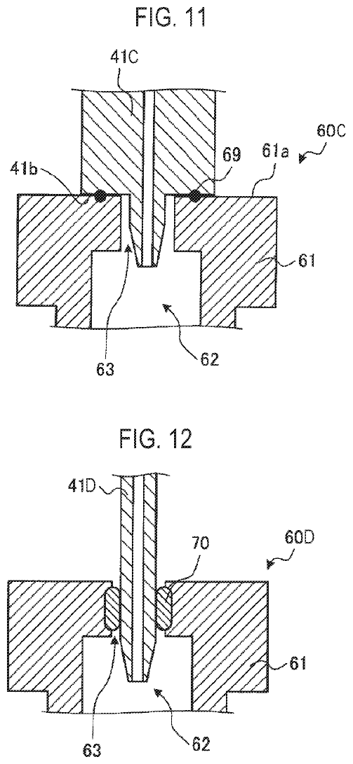

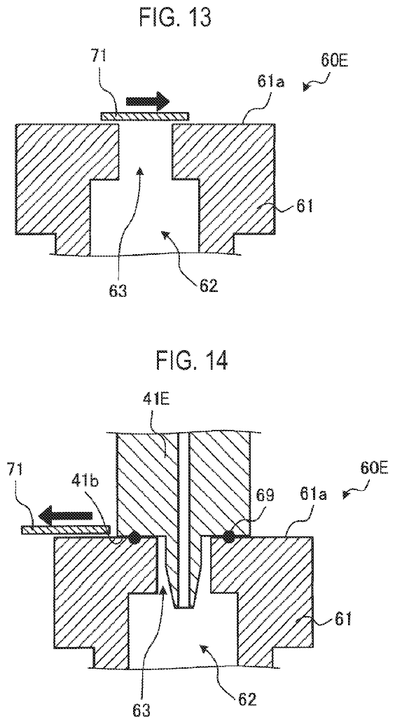

FIG. 12 is a view illustrating a configuration of an atmosphere blocking mechanism according to a fourth modification of the embodiment. As illustrated in FIG. 12, an expansion seal 70 is provided in the opening 63 of a standby section 60D. The expansion seal 70 is configured to he able to expand or contract at a desired timing using various media such as air or water.

The processing unit 16 of the fourth modification is capable of sealing the outside of the standby section 60D (e.g., around the wafer W) and the standby room 62 from each other by expanding the expansion seal 70 to come into close contact with a nozzle 41D when the nozzle 41D is on standby in the standby section 60D. That is to say, in the fourth modification, the expansion seal 70 constitutes a seal mechanism.

Therefore, according to the fourth modification, it is possible to suppress the atmosphere in the circulation path X illustrated in FIG. 4 and the atmosphere around the wafer W from being mixed with each other when the nozzle 41D is on standby in the standby section 60D.

FIGS. 13 and 14 are views illustrating a configuration of an atmosphere blocking mechanism according to a fifth modification of the embodiment. As illustrated in FIG. 13, a standby section 60E of the fifth modification includes a shutter 71 configured to move along the upper surface 61a, and open/close the opening 63.

As illustrated in FIG. 13, the processing unit 16 of the fifth modification is capable of blocking the outside of the standby section 60E (e.g., around the wafer W) and the standby room 62 from each other by closing the opening 63 with the shutter 71 when a nozzle 41E is released from the standby section 60E.

Therefore, according to the fifth modification, it is possible to suppress the atmosphere in the circulation path X illustrated in FIG. 4 and the atmosphere around the wafer W from being mixed with each other when the nozzle 41E is released from the standby section 60E.

In addition, as illustrated in FIG. 14, the processing unit 16 of the fifth modification operates the shutter 71 to open the opening 63 when the nozzle 41E is on standby in the standby section 60E. The processing unit 16 of the fifth modification is capable of sealing the outside of the standby section 60E and the standby room 62 from each other by bringing the O-ring 69 provided on the lower surface 41b of the nozzle 41E into close contact with the upper surface 61a of the standby section 60E in the same manner as the third modification.

That is to say, according to the fifth modification, it is possible to suppress the atmosphere in the circulation path X and the atmosphere around the wafer W from being mixed with each other either when the nozzle 41E is on standby in the standby section 60E or when the nozzle 41E is released from the standby section 60E.

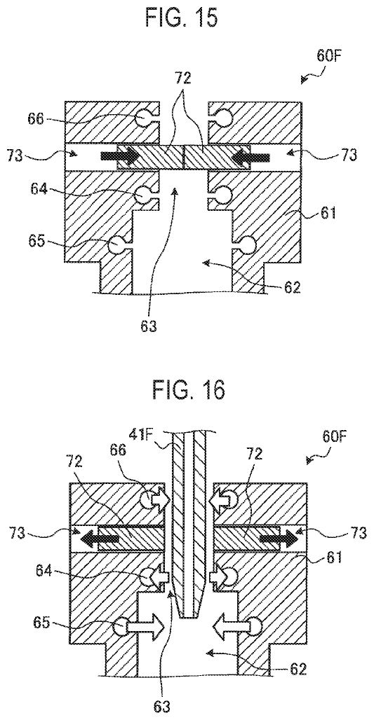

FIGS. 15 and 16 are views illustrating a configuration of an atmosphere blocking mechanism according to a sixth modification of the embodiment. As illustrated in FIG. 15, a standby section 60F of the sixth modification includes a plurality of shutters 72 configured to move inside the opening 63, and open/close the opening 63.

The shutters 72 are movable along a plurality of slits 73 formed in a substantially horizontal direction from the opening 63. The standby section 60F of the sixth modification includes a gas suction portion 64 and gas ejection portions 65 and 66 as in the first modification.

As illustrated in FIG. 15, the processing unit 16 of the sixth modification is capable of blocking the outside of the standby section 60F and the standby room 62 from each other by closing the opening 63 with the plurality of shutters 72 when the nozzle 41F is released from the standby section 60F.

Therefore, according to the sixth modification, it is possible to suppress the atmosphere in the circulation path X illustrated in FIG. 4 and the atmosphere around the wafer W from being mixed with each other when the nozzle 41F is released from the standby section 60F.

In addition, as illustrated in FIG. 16, the processing unit 16 of the sixth modification operates the plurality of shutters 72 to open the opening 63 when the nozzle 41F is on standby in the standby section 60F. The processing unit 16 of the sixth modification sucks the atmosphere of the opening 63 from the gas suction portion 64 and ejects the inert gas from the gas ejection portions 65 and 66 toward the opening 63 or the vicinity of the opening 63.

Thus, when the nozzle 41F is on standby in the standby section 60F, it is possible for the processing unit 16 of the sixth modification to suppress the atmosphere outside the standby section 60F from flowing into the standby room 62 through the opening 63.

That is to say, according to the sixth modification, it is possible to suppress the atmosphere in the circulation path X and the atmosphere around the wafer W from being mixed with each other either when the nozzle 41F is on standby in the standby section 60F or when the nozzle 41F is released from the standby section 60F.

In the above-described various modifications, although the examples in which the atmosphere blocking mechanisms are configured by combining the configurations of the first modification and the third modification and the shutters 71 and 72 have been described, additional atmosphere blocking mechanisms may be configured by combining configurations of the other modifications and the shutters 71 and 72.

### <Detailed Configuration of Discharge Path>

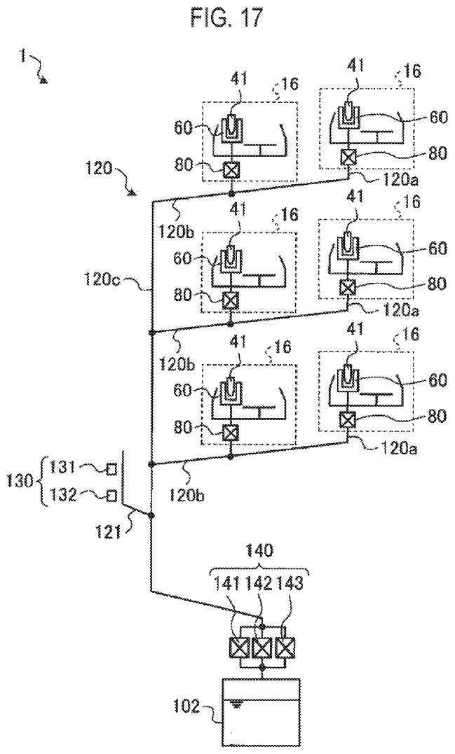

Next, a specific configuration of the discharge path 120 in the substrate processing system 1 will be described with reference to FIG. 17. FIG. 17 is a view illustrating a specific configuration of the discharge path 120 according to the embodiment. In the following, a case will be described in which the processing units 16 in the substrate processing system 1 are arranged two by two in the horizontal direction and are stacked in three stages in the vertical direction.

As illustrated in FIG. 17, the discharge path 120 includes first discharge paths 120a, second discharge paths 120b, and a third discharge path 120c.

The first discharge path 120a of the discharge path 120 extends downward from the standby section 60 of the processing unit 16. That is to say, the discharge path 120 includes the first discharge paths 120a having the same number (six in FIG. 7) as that of the processing units 16. The blocking valve 80 is provided in each of the first discharge paths 120a.

The second discharge path 120b of the discharge path 120 interconnects the first discharge paths 120a of the processing units 16 aligned in the horizontal direction, and extends to be slightly inclined in the horizontal direction. That is to say, the discharge path 120 includes the second discharge paths 102b having the same number (three in FIG. 17) as the stack number of the processing units 16.

The third discharge path 120c of the discharge path 120 interconnects the plurality of second discharge paths 120b and that extends downward. In the example illustrated in FIG. 17, one third discharge path 120c is commonly used. The third discharge path 120c is connected to the tank 102 disposed (e.g., by a distance of about 10 meter) below all the processing units 16.

The processing liquids which have been subjected to the dummy-dispensing process in the standby sections 60 of the processing units 16 are returned to the tank 102 through the first discharge paths 120a, the second discharge paths 120, and the third discharge path 120c by their own gravities.

Here, since the tank 102 is disposed considerably lower than the processing units 16, flow velocities of the processing liquids passing through the discharge path 120 may be excessively increased due to their head drops, which cause air bubbles in the processing liquids. This may cause problems such as an increase in amount of dissolved oxygen in the processing

Therefore, in the embodiment, in order to suppress such a problem, a liquid level sensor 130 and a control valve 140 are provided in the discharge path 120. Configurations and operations of the liquid level sensor 130 and the control valve 140 will be described below.

The liquid level sensor 130 is provided in a branch path 121, which is branched from the third discharge path 120c and extends upward. The liquid level sensor 130 includes a first liquid level sensor 131 and a second liquid level sensor 132.

The first liquid level sensor 131 outputs an ON signal when a liquid level in the discharge path 120 becomes equal to or higher than a predetermined first liquid level, and outputs an OFF signal when the liquid level in the discharge path 120 becomes lower than the predetermined first liquid level. The second liquid level sensor 132 outputs an ON signal when the liquid level in the discharge path 120 becomes equal to or higher than a predetermined second liquid level, and outputs an OFF signal when the liquid level in the discharge path 120 becomes lower than the predetermined second liquid level.

In addition, the second liquid level is set to a position lower than the first liquid level. That is to say, the second liquid level sensor 132 is provided at a position lower than the first liquid level sensor 131. Furthermore, the first liquid level is set to a position lower than the lowest standby section 60 among the standby sections 60 of the plurality of processing units 16.

The control valve 140 is provided at the downstream side of the third discharge path 120c from the position at which the branch path 121 is branched, and controls a flow rate of the processing liquid flowing through the discharge path 120. For example, the control valve 140 includes a first control valve 141, a second control valve 142, and a third control valve 143. The first control valve 141, the second control valve 142, and the third control valve 143 are arranged in parallel.

Sizes of respective valves are set such that the flow rate of the processing liquid ejected when the dummy dispensing process is performed in all the six processing units 16 is equal to that of the processing liquid flowing when the first control valve 141, the second control valve 142 and the third control valve 143 remain in an opened state.

In addition, the sizes of respective valves are set such that the flow rate of the processing liquid ejected when the dummy dispensing process is performed in four processing units 16 among the six processing units 16 is equal to that of the processing liquid flowing when the second control valve 142 and the third control valve 143 remain in an opened state.

Furthermore, the size of the third control valve 143 is set such that the flow rate of the processing liquid ejected when the dummy dispensing process is performed in two processing units 16 among the six processing units 16 is equal to that of the processing liquid flowing when the third control valve 143 remains in an opened state.

### <Behavior Pattern of Control Valve>

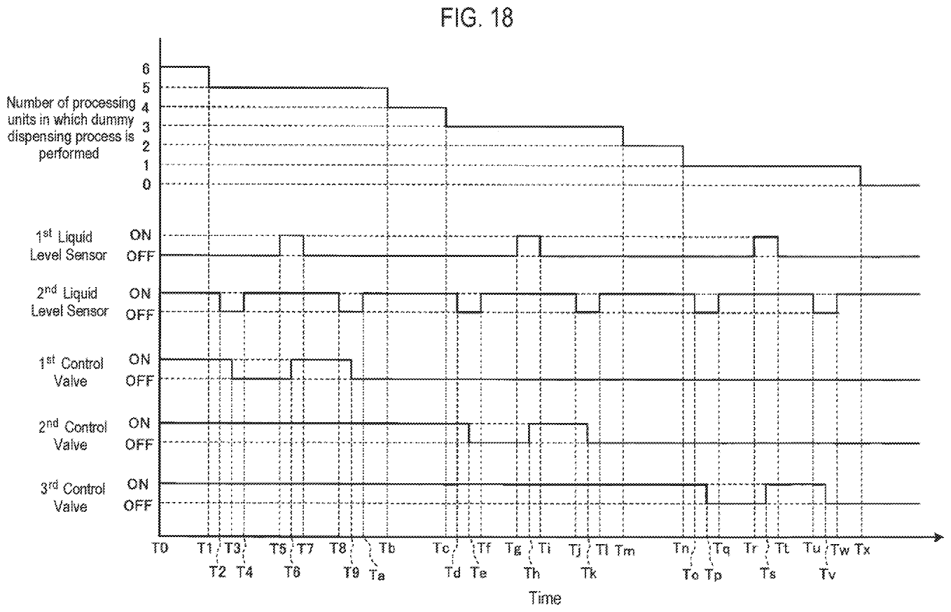

Next, a specific example of a behavior pattern of the control valve 140 will be described with reference to FIG. 18. FIG. 18 is a timing chart illustrating the specific example of the behavior pattern of the control valve 140 according to the embodiment. The control valve 140 is controlled by the controller 18.

At time T0, the number of processing units 16 in which the dummy dispensing process is performed is six. Therefore, by setting all the first control valve 141, the second control valve 142 and the third control valve 143 to the ON (opened) state, it is possible to maintain the liquid level in the discharge path 120 constant.

In addition, at time T0, the liquid level in the discharge path 120 is maintained constant between the first liquid level and the second liquid level. Therefore, the first liquid level sensor 131 outputs an OFF signal, and the second liquid level sensor 132 outputs an ON signal.

Subsequently, at time T1, the number of processing units 16 in which the dummy dispensing process is performed is reduced from six to five. Then, the flow rate of the processing liquid flowing through the discharge path 120 is reduced. Thus, the liquid level in the discharge path 120 is lowered. At time T2, when the liquid level in the discharge path 120 becomes lower than the second liquid level, the second liquid level sensor 132 outputs an OFF signal.

As described above, when the OFF signal is outputted from the second liquid level sensor 132, the controller 18 closes (turns OFF) the first control valve 141 (at time T3). Then, the flow rate of the processing liquid passing through the control valve 140 decreases. Thus, the liquid level in the discharge path 120 increases. At time T4, when the liquid level in the discharge path 120 becomes equal to or higher than the second liquid level, the second liquid level sensor 132 outputs an ON signal.

Thereafter, when the liquid level in the discharge path 120 continues to rise and the liquid level in the discharge path 120 becomes equal to or higher than the first liquid level at time T5, the first liquid level sensor 131 outputs an ON signal.

As described above, when the ON signal is outputted from the first liquid level sensor 131, the controller 18 opens the first control valve 141 (at time T6). Then, the flow rate of the processing liquid passing through the control valve 140 is increased. Thus, the liquid level in the discharge path 120 is lowered. At time T7, when the liquid level in the discharge path 120 becomes lower than the first liquid level, the first liquid level sensor 131 outputs an OFF signal.

Thereafter, when the liquid level in the discharge path 120 continues to be lowered and the liquid level in the discharge path 120 becomes lower than the second liquid level at time T8, the second liquid level sensor 132 outputs an OFF signal.

As described above, when the OFF signal is outputted from the second liquid level sensor 132, the controller 18 closes the first control valve 141 (at time T9). Then, the flow rate of the processing liquid passing through the control valve 140 decreases. Thus, the liquid level in the discharge path 120 increases. At time Ta, when the liquid level in the discharge path 120 becomes equal to or higher than the second liquid level, the second liquid level sensor 132 outputs an ON signal.

As described thus far, when the number of processing units 16 in which the dummy dispensing process is performed is five, the controller 18 opens/closes the first control valve 141 based on the outputs from the first liquid level sensor 131 and the second liquid level sensor 132. Thus, the controller 18 can maintain the liquid level in the discharge path 120 between the first liquid level and the second liquid level.

Therefore, according to the embodiment, it is possible to reduce the head drop of the processing liquid discharged from the standby section 60, thus suppressing the generation of air bubbles in the processing liquid passing through the discharge path 120.

Subsequently, at time Tb, the number of processing units 16 in which the dummy dispensing process is performed is reduced from five to four. In this case, by closing the first control valve 141 and opening the second control valve 142 and the third control valve 143, the flow rate of the processing liquid subjected to the dummy dispensing process and the flow rate of the processing liquid flowing through the control valve 140 are balanced.

Therefore, the liquid level in the discharge path 120 is maintained constant between the first liquid level and the second liquid level.

Subsequently, at time Tc, the number of processing units 16 in which the dummy dispensing process is performed is reduced from four to three. Then, the flow rate of the processing liquid flowing through the discharge path 120 is reduced. Thus, the liquid level in the discharge path 120 is lowered. At time Td, when the liquid level in the discharge path 120 becomes lower than the second liquid level, the second liquid level sensor 132 outputs an OFF signal.

As described above, when the OFF signal is outputted from the second liquid level sensor 132, the controller 18 closes the second control valve 142 (at time Te). Then, the flow rate of the processing liquid passing through the control valve 140 decreases. Thus, the liquid level in the discharge path 120 increases. At time Tf, when the liquid level in the discharge path 120 becomes equal to or higher than the second liquid level, the second liquid level sensor 132 outputs an ON signal.

Thereafter, when the liquid level in the discharge path 120 continues to rise and the liquid level in the discharge path 120 becomes equal to or higher than the first liquid level at time Tg, the first liquid level sensor 131 outputs an ON signal.

As described above, when the ON signal is outputted from the first liquid level sensor 131, the controller 18 opens the second control valve 142 (at time Th). Then, the flow rate of the processing liquid passing through the control valve 140 increases. Thus, the liquid level in the discharge path 120 is lowered. At time Ti, when the liquid level in the discharge path 120 becomes lower than the first liquid level, the first liquid level sensor 131 outputs an OFF signal.

Thereafter, when the liquid level in the discharge path 120 continues to be lowered and the liquid level in the discharge path 120 becomes lower than the second liquid level at time Tj, the second liquid level sensor 132 outputs OFF signal.

As described above, when the OFF signal is outputted from the second liquid level sensor 132, the controller 18 closes the second control valve 142 (at time Tk). Then, the flow rate of the processing liquid passing through the control valve 140 decreases. Thus, the liquid level in the discharge path 120 increases. At time T1, when the liquid level in the discharge path 120 becomes equal to or higher than the second liquid level, the second liquid level sensor 132 outputs an ON signal.

As described thus far, when the number of processing units 16 in which the dummy dispensing process is performed is three, the controller 18 opens/closes the second control valve 142 based on the outputs from the first liquid level sensor 131 and the second liquid level sensor 132. Thus, the controller 18 can maintain the liquid level in the discharge path 120 between the first liquid level and the second liquid level.

Therefore, according to the embodiment, it is possible to reduce the head drop of the processing liquid discharged from the standby section 60, thus suppressing the generation of air bubbles in the processing liquid passing through the discharge path 120.

Subsequently, at time Tm, the number of processing units 16 in which the dummy dispensing process is performed is reduced from three to two. In this case, by closing the first control valve 141 and the second control valve 142 and opening the third control valve 143, the flow rate of the processing liquid subjected to the dummy dispensing process and the flow rate of the processing liquid flowing through the control valve 140 are balanced.

Therefore, the liquid level in the discharge path 120 is maintained constant between the first liquid level and the second liquid level.

Subsequently, at time Tn, the number of processing units 16 in which the dummy dispensing process is performed is reduced from two to one. Then, the flow rate of the processing liquid flowing through the discharge path 120 is reduced and the liquid level in the discharge path 120 is lowered. At time To, when the liquid level in the discharge path 120 becomes lower than the second liquid level, the second liquid level sensor 132 outputs an OFF signal.

As described above, when the OFF signal is outputted from the second liquid level sensor 132, the controller 18 closes the third control valve 143 (at time Tp). Then, the processing liquid does not flow through the control valve 140. Thus, the liquid level in the discharge path 120 increases. At time Tq, when the liquid level in the discharge path 120 becomes equal to or higher than the second liquid level, the second liquid level sensor 132 outputs an ON signal.

Thereafter, when the liquid level in the discharge path 120 continues to rise and the liquid level in the discharge path 120 becomes equal to or higher than the first liquid level at time Tr, the first liquid level sensor 131 outputs an ON signal.

As described above, when the ON signal is outputted from the first liquid level sensor 131, the controller 18 opens the third control valve 143 (at time Ts). Then, the flow rate of the processing liquid passing through the control valve 140 is increased and the liquid level in the discharge path 120 is lowered. At time Tt, when the liquid level in the discharge path 120 becomes lower than the first liquid level, the first liquid level sensor 131 outputs an OFF signal.

Thereafter, when the liquid level in the discharge path 120 continues to be lowered and the liquid level in the discharge path 120 becomes lower than the second liquid level at time Tu, the second liquid level sensor 132 outputs an OFF signal.

As described above, when the OFF signal is outputted from the second liquid level sensor 132, the controller 18 closes the third control valve 143 (at time Tv). Then, the processing liquid does not flow through the control valve 140. Thus, the liquid level in the discharge path 120 increases. At time Tw, when the liquid level in the discharge path 120 becomes equal to or higher than the second liquid level, the second liquid level sensor 132 outputs an ON signal.

As described thus far, when the number of processing units 16 in which the dummy dispensing process is performed is one, the controller 18 opens/closes the third control valve 143 based on the outputs from the first liquid level sensor 131 and the second liquid level sensor 132. Thus, the controller 18 can maintain the liquid level in the discharge path 120 between the first liquid level and the second liquid level.

Therefore, according to the embodiment, it is possible to reduce the head drop of the processing liquid discharged from the standby section 60, thus suppressing the generation of air bubbles in the processing liquid passing through the discharge path 120.

Finally, at time Tx, the number of processing units 16 in which the dummy dispensing process is performed is reduced from one to zero. In this case, the processing liquid does not flow through the control valve 140 by closing all the first control valve 141, the second control valve 142, and the third control valve 143. Thus, the liquid level in the discharge path 120 is maintained constant between the first liquid level and the second liquid level.

As described above, in the embodiment, control is performed such that the first control valve 141, the second control valve 142, and the third control valve 143 are opened/closed independently of one another depending on the number of processing units 16 in which the dummy dispense process is performed.

Assuming that a plurality of valves are controlled to be simultaneously opened/closed depending on the number of processing units 16 in which the dummy dispensing process is performed, time lag that occurs when opening/closing the respective valves may cause a problem that the processing liquid flows at a flow rate different from a desired flow rate.

However, in the embodiment, by controlling the first control valve 141, the second control valve 142, and the third control valve 143 to open/close independently of one another rather than a simultaneous manner, it is possible to suppress the problem caused due to such time lags.

In the embodiment, as illustrated in FIG. 17, the first liquid level sensor 131 and the second liquid level sensor 132 are disposed below the lowest standby section 60 and in proximity to the standby section 60, and the control valve 140 is disposed close to the tank 102.

By disposing the first liquid level sensor 131 and the second liquid level sensor 132 below the lowest standby section 60 and in proximity to the standby section 60 as described above, it is possible to set the liquid level in the discharge path 120 to be in the vicinity of the standby section 60. Therefore, according to the embodiment, it is possible to suppress a large amount of atmosphere from entering the inside of the discharge path 120.

In addition, by disposing the control valve 140 close to the tank 102, it is possible to suppress generation of air bubbles in the processing liquid, which is caused as the processing liquid in the discharge path 120 vigorously flows into the tank 102 when the control valve 140 is opened.

### <Modifications of Discharge Path>

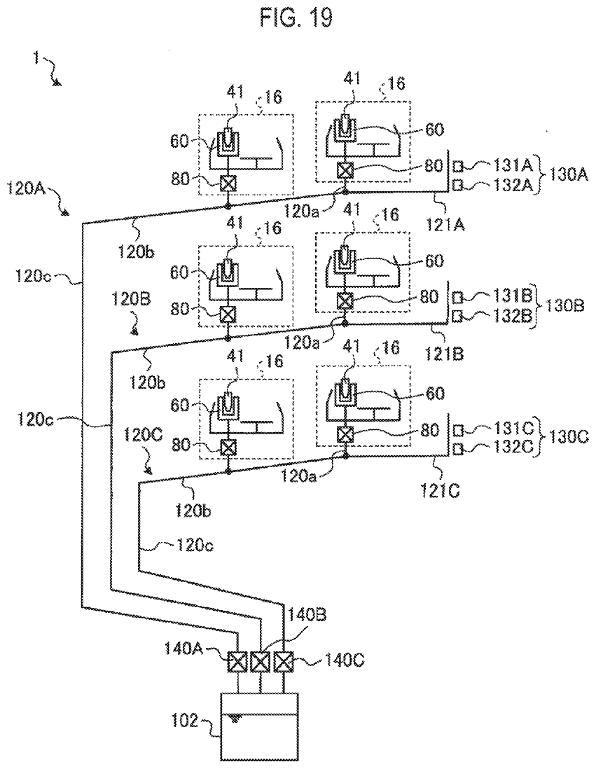

Next, various modifications of the discharge path 120 will be described with reference to FIGS. 19 to 22. FIG. 19 is a view illustrating a specific configuration of discharge paths 120A to 120C according to a seventh modification of the embodiment. The seventh modification is different from the embodiment in that the discharge paths 120A to 120C are provided in respective stages of the processing units 16.

As illustrated in FIG. 19, a substrate processing system 1 of the seventh modification is provided with the discharge path 120A that interconnects the two processing units 16 at the upper stage and the tank 102, and the discharge path 120B that interconnects the two processing units 16 at the intermediate stage and the tank 102. In addition, the substrate processing system 1 of the seventh modification is provided with the discharge path 120C that interconnects the two processing units 16 at the lower stage and the tank 102.

Each of the discharge paths 120A, 120B, and 120C includes the first discharge path 120a, the second discharge path 120b, and the third discharge path 120c, similarly to the discharge path 120 of the embodiment.

The discharge path 120A includes a branch path 121A branched from the second discharge path 120b. A liquid level sensor 130A is provided in the branch path 121A. In addition, a control valve 140A is provided in the third discharge path 120c of the discharge path 120A.

The discharge path 120B includes a branch path 121B branched from the second discharge path 120b. A liquid level sensor 130B is provided in the branch path 121B. In addition, a control valve 140B is provided in the third discharge path 120c of the discharge path 120B.

The discharge path 120C includes a branch path 121C branched from the second discharge path 120b. A liquid level sensor 130C is provided in the branch path 121C. In addition, a control valve 140C is provided in the third discharge path 120c of the discharge path 120C.

In the discharge paths 120A to 120C, the arrangement and configuration of the liquid level sensors 1304 to 130C are the same as in the embodiment. Furthermore, the sizes of the control valves 140A to 140C are set such that the flow rate of the processing liquid ejected when the dummy dispensing process is performed in two processing units 16 is equal to that of the processing liquid flowing when the control valves 140A to 1400 are opened.

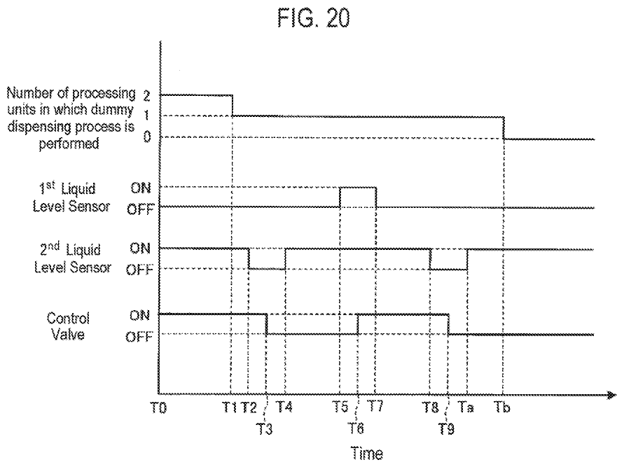

Next, a specific example of the behavior pattern of the control valve 140A in the seventh modification will be described with reference to FIG. 20. FIG. 20 is a timing chart illustrating a specific example of the behavior pattern of the control valve 140A according to the seventh modification of the embodiment.

At time T0, the number of processing units 16 in which the dummy dispensing process is performed is two. Therefore, by opening the control valve 140A, it is possible to maintain the liquid level in the discharge path 120A constant.

In addition, at lime T0, the liquid level in the discharge path 120A is maintained constant between the first liquid level and the second liquid level. Therefore, the first liquid level sensor 131A outputs an OFF signal, and the second liquid level sensor 132A outputs an ON signal.

Subsequently, at time T1, the number of processing units 16 in which the dummy dispensing process is performed is reduced from two to one. Then, the flow rate of the processing liquid flowing through the discharge path 120A is reduced and the liquid level in the discharge path 120A is lowered. At time T2, when the liquid level in the discharge path 120A becomes lower than the second liquid level, the second liquid level sensor 132A outputs an OFF

As described above, when the OFF signal is outputted from the second liquid level sensor 132A, the controller 18 closes the control valve 140A (at time T3). Then, the processing liquid does not flow through the control valve 140A and the liquid level in the discharge path 120A is increased. At time T4, when the liquid level in the discharge path 120A becomes equal to or higher than the second liquid level, the second liquid level sensor 132A outputs an ON signal.

Thereafter, when the liquid level in the discharge path 120A continues to rise and the liquid level in the discharge path 120A becomes equal to or higher than the first liquid level at time T5, the first liquid level sensor 131A outputs an ON signal.

As described above, when the ON signal is outputted from the first liquid level sensor 131A, the controller 18 opens the control valve 140A (at time T6). Then, the flow rate of the processing liquid passing through the control valve 140A is increased and the liquid level in the discharge path 120A is lowered. At time T7, when the liquid level in the discharge path 120A becomes lower than the first liquid level, the first liquid level sensor 131A outputs an OFF signal.

Thereafter, when the liquid level in the discharge path 120A continues to be lowered and the liquid level in the discharge path 120A becomes lower than the second liquid level at time T8, the second liquid level sensor 132A outputs an OFF signal.

As described above, when the OFF signal is outputted from the second liquid level sensor 132A, the controller 18 closes the control valve 140A (at time 19). Then, the processing liquid does not flow through the control valve 140A and the liquid level in the discharge path 120A is increased. At time Ta, when the liquid level in the discharge path 120A becomes equal to or higher than the second liquid level, the second liquid level sensor 1324 outputs an ON signal.

As described thus far, when the number of processing units 16 in which the dummy dispensing process is performed is one, the controller 18 opens/closes the control valve 140A based on the outputs from the first liquid level sensor 131A and the second liquid level sensor 132A. Thus, the controller 18 can maintain the liquid level the discharge path 120A between the first liquid level and the second liquid level.

Therefore, according to the seventh modification, it is possible to reduce the head drop of the processing liquid discharged from the standby section 60, thus suppressing the generation of air bubbles in the processing liquid passing through the discharge path 120A.

Finally, at time Tb, the number of processing units 16 in which the dummy dispensing process is performed is reduced from one to zero, in this case, the processing liquid does not flow through the control valve 140A by closing the control valve 140A. Thus, the liquid level is maintained constant between the first liquid level and the second liquid level.

Controlling the control valve 140B and the control valve 140C in the discharge path 120B and the discharge path 120C, respectively, is the same as described above.

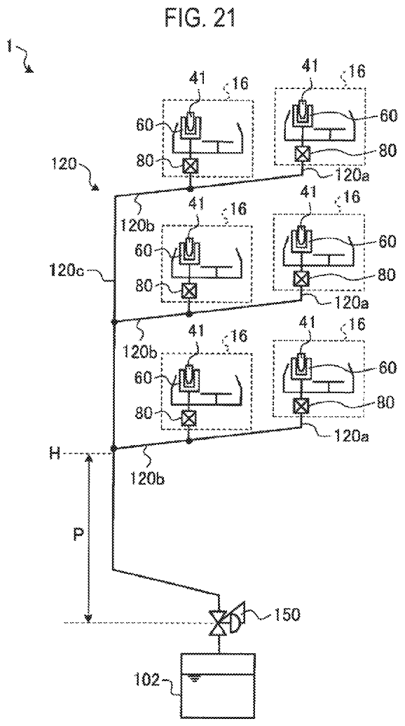

FIG. 21 is a view illustrating a specific configuration of a discharge path 120 according to an eighth modification of the embodiment. The eighth modification is different from the embodiment in that a backing pressure valve 150 is provided in the discharge path 120 instead of the liquid level sensor 130 and the control valve 140.

As illustrated in FIG. 21, in the substrate processing system 1 of the eighth modification, the backing pressure valve 150 is provided in the discharge path 120. Then, by setting a primary pressure of the backing pressure valve 150 to a predetermined hydraulic head pressure P, it is possible to control the processing liquid in the discharge path 120 to a predetermined liquid level H.

Therefore, according to the eighth modification, it is possible to reduce the head drop of the processing liquid discharged from the standby section 60, thus suppressing the generation of air bubbles in the processing liquid passing through the discharge path 120.

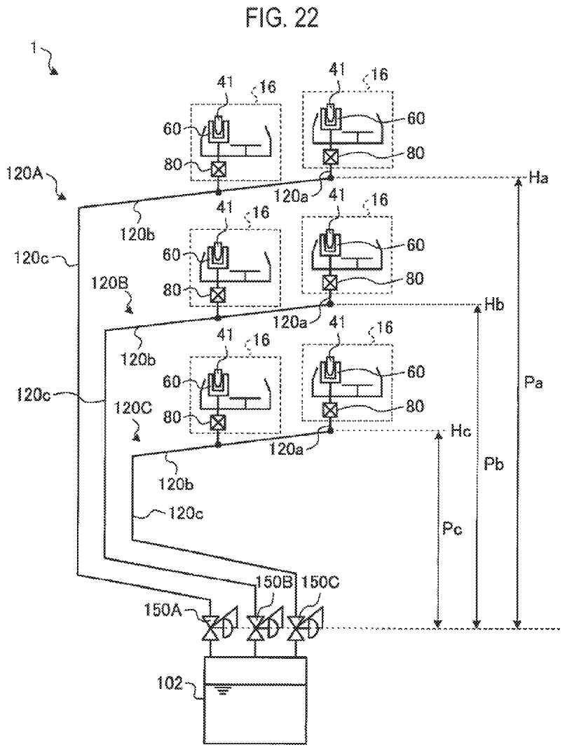

FIG. 22 is a view illustrating a specific configuration of discharge paths 120A to 120C according to a ninth modification of the embodiment. The ninth modification is different from the embodiment in that backing pressure valves 150A to 150C are respectively provided in the discharge paths 120A to 120C instead of the liquid level sensors 130A to 130C and the control valve 140A to 140C.

As illustrated in FIG. 22, the substrate processing system 1 of the ninth modification includes the backing pressure valve 150A provided in the discharge path 120A, the backing pressure valve 150B provided in the discharge path 120B, and the backing pressure valve 150C provided in the discharge path 120C.

By setting a primary pressure of the backing pressure valve 150A to a predetermined hydraulic head pressure Pa, it is possible to control the processing liquid in the discharge path 120A to a predetermined liquid level Ha. In addition, by setting a primary pressure of the backing pressure valve 150B to a predetermined hydraulic head pressure Pb, it is possible to control the processing liquid in the discharge path 120B to a predetermined liquid level Hb.

In addition, by setting a primary pressure of the backing pressure valve 150C to a predetermined hydraulic head pressure Pc, it is possible to control the processing liquid in the discharge path 120C to a predetermined liquid level Hc.

Therefore, according to the ninth modification, it is possible to reduce the head drop of the processing liquid discharged from the standby sections 60 in all the discharge paths 120A to 120C, thus suppressing the generation of air bubbles in the processing liquid passing through the discharge paths 120A to 120C.

In the above embodiment, the example in which the processing units 16 in the substrate processing system 1 are arranged two by two in the horizontal direction has been described. However, the number of processing units 16 arranged in the horizontal direction is not limited to two. In the above embodiment, although the case in which the processing units 16 in the substrate processing system 1 are configured to be stacked in three stages in the vertical direction has been described, the stack number of the processing units 16 in the vertical direction is not limited to three stages.

The substrate processing apparatus (substrate processing system 1) according to the embodiment includes the nozzle 41, the standby section 60, the supply path 110, the discharge path 120, the circulation path X, and the atmosphere blocking mechanism. The nozzle 41 ejects the processing liquid onto the substrate (wafer W). The standby section 60 has the opening 63. The nozzle 41 is inserted into the opening 63 to stand by in the standby section 60. The supply path 110 supplies the processing liquid to the nozzle 41. The discharge path 120 discharges the processing liquid from the standby section 60. The circulation path X is formed by connecting the nozzle 41, the standby section 60, the supply path 110, and the discharge path 120. The atmosphere blocking mechanism is provided in the circulation path X, and blocks the inside of the circulation path X and the surrounding of the substrate (wafer W) from each other. This makes it possible to suppress the mixing of the atmosphere in the circulation path X and the atmosphere around the wafer W.

In addition, in the substrate processing apparatus (substrate processing system 1) according to the embodiment, the discharge path 120 includes the blocking valve 80 configured to block the inflow of the processing liquid from the standby section 60 to the discharge path 120. The atmosphere blocking mechanism is the blocking valve 80. Therefore, when the nozzle 41 is released from the standby section 60, it is possible to suppress the atmosphere in the circulation path X and the atmosphere around the wafer W from being mixed with each other.

In addition, in the substrate processing apparatus (substrate processing system 1) according to the embodiment, the atmosphere blocking mechanism is the shutters 71 and 72 configured to open/close the opening 63. Therefore, when the nozzle 41 is released from the standby section 60, it is possible to suppress the atmosphere in the circulation path X and the atmosphere around the wafer W from being mixed with each other.

In addition, in the substrate processing apparatus (substrate processing system 1) according to the embodiment, the atmosphere blocking mechanism includes the gas suction portion 64 and the gas ejection portions 65 and 66, which are connected in the opening 63 or in the vicinity of the opening 63. Thus, either when the nozzle 41 is on standby in the standby section 60 or when the nozzle 41 is released from the standby section 60, it is possible to suppress the atmosphere in the circulation path X and the atmosphere around the wafer W from being mixed with each other.

In addition, in the substrate processing apparatus (substrate processing system 1) according to the embodiment, the atmosphere blocking mechanism is a seal mechanism that seals the nozzle 41 and the standby section 60 (the water seal 68, the O-ring 69, and the expansion seal 70) from each other. Therefore, when the nozzle 41 is on standby in the standby section 60, it is possible to suppress the atmosphere in the circulation path X and the atmosphere around the wafer W from being mixed with each other.

The substrate processing apparatus (substrate processing system 1) according to the embodiment further includes the tank 102 provided below the standby section 60 and connected to the supply path 110 and the discharge path 120 so as to store the processing liquid. Therefore, it is possible to stably supply the processing liquid stored in the tank 102 to the wafer W.

In the substrate processing apparatus(substrate processing system 1) according to the embodiment, the discharge path 120 includes the liquid level sensor 130 configured to detect the liquid level of the processing liquid in the discharge path 120, and the control valve 140 configured to control the inflow of the processing liquid to the tank 102 from the discharge path 120. Therefore, it is possible to reduce the head drop of the processing liquid discharged from the standby section 60, thus suppressing the generation of air bubbles in the processing liquid passing through the discharge path 120.

In the substrate processing apparatus (substrate processing system 1) according to the embodiment, the liquid level sensor 130 is disposed below the lowest standby section 60 and close to the lowest standby section 60. The control valve 140 is disposed close to the tank 102. Therefore, it is possible to suppress a large amount of atmosphere from entering the discharge path 120, thus suppressing bubbles from being generated in the processing liquid.

In addition, in the substrate processing apparatus (substrate processing system 1) according to the embodiment, the discharge path 120 includes the backing pressure valve 150. Therefore, it is possible to reduce the head drop of the processing liquid discharged from the standby section 60, thus suppressing the generation of air bubbles in the processing liquid passing through the discharge path 120.

The substrate processing method according to an embodiment, which is used in the substrate processing apparatus (substrate processing system 1) described above, includes ejecting the processing liquid from the nozzle 41 and circulating the same through the circulation path X in the state in which the nozzle 41 is on standby in the standby section 60. In addition, the substrate processing method includes blocking the inside of the circulation path X and the surrounding of the substrate (wafer W) from each other using the atmosphere blocking mechanism, in the state where the nozzle 41 is ejecting the processing liquid to the substrate (wafer W). Therefore, it is possible to suppress the mixing of the atmosphere in the circulation path X and the atmosphere around the wafer W.

In the substrate processing method according to the embodiment, when the liquid level of the processing liquid in the discharge path 120 becomes equal to or higher than the predetermined first liquid level in the substrate processing apparatus (substrate processing system 1) described above, the control valve 140 is opened. In addition, when the liquid level of the processing liquid in the discharge path 120 becomes equal to or lower than a predetermined second liquid level lower than the first liquid level, the control valve 140 is throttle. Therefore, it is possible to reduce the head drop of the processing liquid discharged from the standby section 60, thus suppressing the generation of air bubbles in the processing liquid passing through the discharge path 120.

In the substrate processing method according to the embodiment, the first liquid level is lower than the height of the standby section 60. Therefore, it is possible to suppress the processing liquid from flowing backward from the discharge path 120 and overflowing from the standby section 60.

Although the embodiments of the present disclosure have been described above, the present disclosure is not necessarily limited to the above-described embodiments, and various modifications can be made without departing from the scope of the present disclosure.

According to the present disclosure, it is possible to stably supply a processing liquid during substrate processing while reducing the processing liquid to be discarded by dummy dispensing or the like.

It should he noted that the embodiments and modifications disclosed herein are exemplary in all respects and are not restrictive. The above-described embodiments and modifications may be omitted, replaced or modified in various forms without departing from the scope and spirit of the appended claims.

What is claimed is:

1. A substrate processing apparatus comprising:
a nozzle configured to eject a processing liquid onto a substrate;
a standby section having an opening, wherein the nozzle is inserted into the opening to stand by in the standby section;
a supply path through which the processing liquid is supplied to the nozzle;
a discharge path through which the processing liquid is discharged from the standby section;
a circulation path formed by connecting the nozzle, the standby section, the supply path, and the discharge path; and
an atmospheric-blocking mechanism provided in the circulation path to block an inside of the circulation path and a surrounding of the substrate from each other.

2. The substrate processing apparatus of claim 1, wherein the discharge path comprises a blocking valve configured to block the processing liquid from inflowing into the discharge path from the standby section, and
wherein the atmosphere blocking mechanism is the blocking valve.

3. The substrate processing apparatus of claim 2, wherein the atmosphere blocking mechanism is a shutter configured to open/close the opening.

4. The substrate processing apparatus of claim 2, wherein the atmosphere blocking mechanism includes a gas suction portion and a gas ejection portion, which are connected to the opening or provided adjacent to the opening.

5. The substrate processing apparatus of claim 2, wherein the atmosphere blocking mechanism is a seal mechanism configured to seal the nozzle and the standby section from each other.

6. The substrate processing apparatus of claim 2, further comprising:
a tank provided below the standby section and connected to the supply path and the discharge path so as to store the processing liquid.

7. The substrate processing apparatus of claim 1, wherein the atmosphere blocking mechanism is a shutter configured to open/close the opening.

8. The substrate processing apparatus of claim 7, wherein the atmosphere blocking mechanism includes a gas suction portion and a gas ejection portion, which are connected to the opening or provided adjacent to the opening.

9. The substrate processing apparatus of claim 7, wherein the atmosphere blocking mechanism is a seal mechanism configured to seal each of the nozzle and the standby section from each other.

10. The substrate processing apparatus of claim 1, wherein the atmosphere blocking mechanism includes a gas suction portion and a gas ejection portion, which are connected to the opening or provided adjacent to the opening.

11. The substrate processing apparatus of claim 1, wherein the atmosphere blocking mechanism is a seal mechanism configured to seal the nozzle and the standby section from each other.

12. The substrate processing apparatus of claim 1, further comprising:
a tank provided below the standby section and connected to the supply path and the discharge path so as to store the processing liquid.

13. The substrate processing apparatus of claim 12, wherein the discharge path includes a backing pressure valve.

14. The substrate processing apparatus of claim 1, further comprising:
a tank provided below the standby section and connected to the supply path and the discharge path so as to store the processing liquid.

15. The substrate processing apparatus of claim 14, wherein the discharge path includes a liquid level sensor configured to detect a liquid level of the processing liquid in the discharge path, and a control valve configured to control an inflow of the processing liquid from the discharge path to the tank.

16. The substrate processing apparatus of claim 15, wherein the standby section includes a plurality of standby sections,
wherein the liquid level sensor is disposed below a lowest standby section among the plurality of standby sections and disposed adjacent to the standby section, and
the control valve is disposed close to the tank.

17. A substrate processing method used in the substrate processing apparatus of claim 15, the method comprising:
opening the control valve when a liquid level of the processing liquid in the discharge path becomes equal to or higher than a predetermined first liquid level; and
throttling the control valve when the liquid level of the processing liquid in the discharge path becomes equal to or lower than a predetermined second liquid level which is lower than the predetermined first liquid level.

18. The substrate processing method of claim 17, wherein the predetermined first liquid level is lower than the standby section.

19. A substrate processing method used in the substrate processing apparatus of claim 1, the method comprising:
ejecting the processing liquid from the nozzle to circulate the processing liquid through the circulation path in a state in which the nozzle is on standby in the standby section; and
blocking the inside of the circulation path and the surrounding of the substrate from each other using the atmosphere-blocking mechanism in a state in which the nozzle is ejecting the processing liquid to the substrate.

20. A non-transitory computer-readable storage medium storing a program that causes a computer to execute the substrate processing method of claim 19.
